(19) United States
(12) Patent Application Publication
(10) Pub. No.: US 2010/0275843 A1
(43) Pub. Date: Nov. 4, 2010

(54) HVPE REACTOR ARRANGEMENT

(76) Inventors: Vladimir Nikolaev, St. Petersburg (RU); Vladislav E. Bougrov, Espoo (RU); Maxim A. Odnoblyudov, Espoo (RU); Arthur Cherenkov, St. Petersburg (RU)

Correspondence Address: FAY SHARPE LLP, 1228 Euclid Avenue, 5th Floor, The Halle Building, Cleveland, OH, 44115, US

(21) Appl. No.: 12/747,587

(22) PCT Filed: Dec. 11, 2008
(86) PCT No.: PCT/FI08/50728

§ 371 Date: Jun. 11, 2010

(30) Foreign Application Priority Data
Dec. 13, 2007 (FI) 20075902

(51) Int. Cl. C23C 16/34

(52) U.S. Cl. 118/715

(57) ABSTRACT

An HVPE reactor arrangement comprises a reaction chamber (1), a gas inlet (2) for introducing process gases to the reaction chamber, a residual gas outlet (3), and a pump (4) for evacuating the residual gases from the reaction chamber via the residual gas outlet, the pump being capable of creating and maintaining in the reaction chamber a pressure less than or equal to about 100 mbar. According to the present invention, the reactor arrangement comprises means (6, 7, V2, V3) for supplying dissolving fluid to the pump for dissolving the possible parasitic deposition of the agents of the residual gases on the pump inner surfaces.

### FIELD OF THE INVENTION

The present invention relates to reduced pressure Hydride Vapor Phase Epitaxy (HVPE) reactors used, for example, for epitaxial growth of GaN-based semiconductor substrates and components. Particularly, the present invention relates to the system for evacuating the reaction chamber.

### BACKGROUND OF THE INVENTION

In the existing HVPE reactors designed for GaN growth, one typical and serious problem is a high rate of parasitic deposition of different materials, especially NH₄Cl and GaCl₃, on the inner surfaces of the reactor particularly near and after the outlet of the process gases. As a result, some of the reactors are blockaded even already after some hours of operation. The problem of blocking concerns the entire exhausting system but particularly the evacuating pump. Said solid compounds make it very difficult to use standard, conventional vacuum pumps for reducing pressure in the reactor. This necessitates specialized systems which in turn lead to high costs. One known solution trying to avoid the plugging of the pump is installing a large condensing chamber prior to the pump. The condensing chamber works as a trap for the residual gases about which a large amount accumulate on the walls of the condensing chamber. However, naturally this solution just postpones the plugging without really solving the primary problem.

Hence, there is a need for an effective, preferably low cost evacuating system enabling continuous operation of a HVPE reactor without interruptions caused by plugging of the gas exhausting system.

### OBJECTIVE OF THE INVENTION

The objective of the present invention is to provide an effective, preferably low cost evacuating system for HVPE reactors, the evacuating system enabling continuous operation of the reactor without interruptions caused by plugging of the gas exhausting system due to the parasitic deposition.

### SUMMARY OF THE INVENTION

The present invention is characterized by what is disclosed in claim 1.

The HVPE reactor arrangement of the present invention comprises a reaction chamber, a gas inlet for introducing process gases to the reaction chamber, a residual gas outlet, and a pump for evacuating the residual gases from the reaction chamber via the residual gas outlet, the pump being capable of creating and maintaining in the reaction chamber a pressure less than or equal to about 100 mbar.

According to the present invention, the reactor arrangement comprises means for supplying dissolving fluid to the pump for dissolving the possible parasitic deposition of the agents of the residual gases on the pump inner surfaces.

Thus, the key feature in the present invention is said means for supplying dissolving fluid to the pump making it possible to dissolve the solid parasitic deposition and to wash it out from the pump and the following exhausting channels. Cleaning the pump this way can be performed not only between the processing periods but also during the process runs. In the case of supplying dissolving fluid during the operation of the reactor equipment, the dissolving fluid can also have another important function in dissolving the residual gases already before the pump so that the depositing or condensing of them on the surfaces of the pump is prevented. Both of said mechanisms preserve the pump from blockage, thus enabling long-term operation of the reactor without interruptions. This means a great advantage when compared to those prior art systems utilizing high-cost but still easily plugging and damaging vacuum pumps.

The pump used in an arrangement according to a present invention can be of any type capable of providing said vacuum and being also capable of transferring, in addition to gases, also liquid and vapor. Possible pump types are, for example, liquid ring pumps, membrane pumps and piston dosing pumps. For example, a liquid ring vacuum pump in industrial ceramic material could be a good choice. A piston dosing pump is a pump based on cyclic back-and-forth operation of a piston. A piston dosing pump usually takes inside it, during the motion of a piston to one direction, a particular fluid volume and pushes it out during the motion of the piston to the opposite direction. Thus, the operation can be said to be pulsed instead of a continuous fluid transfer. In the case of piston dosing pump type, there are preferably at least two pumps which are used asynchronously in order to minimize the pressure fluctuations due to the pulsed type operation of the pump.

The means for supplying dissolving fluid to the pump comprise preferably a dissolving fluid container in a flow connection with the pump intake. The flow connection is preferably controllable with a valve. In one preferred embodiment, a dissolving fluid container is in a flow connection with both the pump intake and outtake forming thus a dissolving fluid circulation path enabling a longer-term usage of the dissolving fluid. In this embodiment, there is preferably also another dissolving fluid container serving as a supplement container for adding clean fluid to the fluid circulation when needed.

Preferably, the reactor arrangement of the present invention comprises also an additional residual gas outlet followed by an ethylene-glycol bubbler which together serve as an alternative residual gas evacuating path for evacuating the residual gases e.g. during purging of the reactor and in other situations where the pump is not used. Water solution of ammonia chloride and other waste products could be very harmful to the reactor parts and back flow of vapor of these solutions during low process gas flows could also affect negatively the growth process. The ethylene-glycol bubbler operates like a valve preventing said back flow.

### DETAILED DESCRIPTION OF THE INVENTION

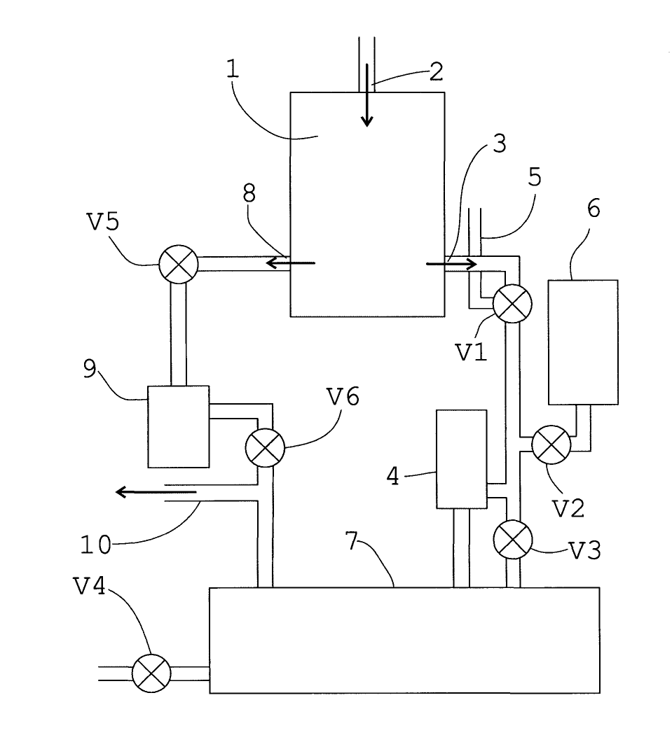

In the following, the present invention is described in more detail with reference to the accompanying FIG. 1 showing a schematic view of a HVPE reactor arrangement according to one embodiment of the present invention.

The reactor arrangement of FIG. 1 comprises a reaction chamber 1 and a process gas inlet 2 for introducing the process gases to the chamber. For simplicity, in FIG. 1 there is shown only one process gas inlet. Naturally, in real equipment, there are usually many of them. For evacuating the residual process gases flown through the chamber, there is a residual gas outlet 3 followed by a configuration comprising a pump 4, the intake of which being arranged in a flow connection with the reaction chamber via the residual gas outlet. In the configuration, between the pump and the residual gas outlet is a two-way first valve V1 to be used for controlling the flow connection between the reaction chamber and the pump. To the two-way first valve is connected also an inert gas line 5 for supplying nitrogen or other inert gas to the pump between its operation periods for cleaning and drying the pump line, i.e. the pump and/or the channels to and from it. Further, connected in a flow connection with the pump intake via a second valve V2 is a distilled water container 6 for storage and supplying to the pump distilled water for dissolving and washing out from the pump the materials from the residual gases accumulated on the inner surfaces of the pump through parasitic deposition. The output of the pump opens to a water tank 7 which, in its turn, is connected back to the intake of the pump via a third valve V3. Thus, there is a water circulation path through the pump and the water tank. There is also a fourth valve V4 connected to the water tank for controlling the water flow out from the tank.

As an alternative residual gas evacuating path, there is an additional residual gas outlet 8 followed by a fifth valve V5, an ethylene-glycol bubbler 9, and a sixth valve V6. This alternative residual gas evacuating path can be used e.g. during the reactor purging sessions or during conditions with a pressure higher than the atmospheric one. The ethylene-glycol bubbler prevents back flow of chemically aggressive compounds to the chamber. The two residual gas evacuating paths finally coincide opening to a common exhaust pipe 10 for transporting the residual gases to a scrubber (not shown in FIG. 1).

The operation of the reactor arrangement of FIG. 1 is shortly described in the following. In a normal process operation, the residual gases are evacuated through the residual gas outlet 3. The fifth and sixth valves V5, V6 are closed while the first valve V1 is open. The pump 4 is used to evacuate the reaction chamber. The third valve V3 is used to control water supply from the water tank to the pump for cleaning the pump by dissolving and washing out the parasitic deposition from the pump inner surfaces. After the pump the water returns to the water tank from which contaminated water can be removed via the fourth valve V4. Pure, distilled water can be added to the water circulation from the distilled water tank via the second valve V2. The pump can be cleaned during the process as well as between the process sessions.

It is important to note that water as the dissolving fluid is just one simple example. Naturally, as is clear for a person skilled in the art, any other suitable fluid or water solution of a suitable agent could be used instead of pure water. For example, HCl, ammonia gases and ammonia chloride could be dissolved more efficiently by some alcohols than by water.

When purging the reactor between the process runs and in other situations where the pumps are not used, the first valve V1 is closed against the reaction chamber and the fifth and sixth valves V5, V6 are open. Thus, the residual gases then flow through the additional residual gas outlet 8 and the ethylene-glycol bubbler 9. The pump 4 can then be dried by a flow of e.g. nitrogen through the two-way valve V1.

As is clear for a person skilled in the art, the present invention is not limited to the example described above. Instead, the embodiments of the present invention can freely vary within the scope of the claims.

1. An HVPE reactor arrangement comprising a reaction chamber, a gas inlet for introducing process gases to the reaction chamber, a residual gas outlet a pump for evacuating the residual gases from the reaction chamber via the residual gas outlet, the pump being capable of creating and maintaining in the reaction chamber a pressure less than or equal to about 100 mbar, and means for supplying dissolving fluid to the pump for dissolving the possible parasitic deposition of the agents of the residual gases on the pump inner surfaces, characterized in that the means for supplying dissolving fluid to the pump comprise a dissolving fluid container in a flow connection with both the pump intake and outtake forming thus a dissolving fluid circulation path.

2. (canceled)

3. An HVPE reactor arrangement according to claim 1, characterized in that the reactor arrangement comprises an additional residual gas outlet followed by an ethylene-glycol bubbler serving as an alternative residual gas evacuating path for evacuating the residual gases e.g. during purging of the reactor.
